(19) United States
(12) Patent Application Publication
(10) Pub. No.: US 2024/0297667 A1
(43) Pub. Date: Sep. 5, 2024

(54) METHOD AND ARRANGEMENTS FOR SUPPORTING FORWARD ERROR CORRECTION DECODING OF A WORD

(71) Applicant: Telefonaktiebolaget LM Ericsson (publ), Stockholm (SE)

(72) Inventors: Hugo TULLBERG, Nyköping (SE); Guido Carlo FERRANTE, Stockholm (SE)

(21) Appl. No.: 18/566,195

(22) PCT Filed: Jun. 2, 2021
(86) PCT No.: PCT/SE2021/050516

§ 371 Date: Dec. 1, 2023

(51) Int. Cl. H03M 13/15; H03M 13/11

(52) U.S. Cl. CPC H03M 13/151; H03M 13/1105; H03M 13/118

(57) ABSTRACT

Supporting forward error correction decoding of a word received over a noisy channel. The word being a codeword according to a linear block code prior to transmission. The syndrome is computed for the received word using an obtained parity check matrix. It is generated one or more noise sequences to affect bits of the received word that are in one or more bit positions identified through parity check equations of the obtained parity check matrix identified as erroneous parity check equations by the computed syndrome. Candidate codewords are formed for the noise sequences, respectively, each candidate codeword corresponding to the received word with removal of noise according to a respective one of the noise sequences. It is determined if any one of the formed candidate codewords is an actual codeword according to the LBC by computing the syndrome for the candidate codeword using the obtained parity check matrix.

### TECHNICAL FIELD

Embodiments herein concern a method and apparatus(es) for forward error correction (FEC) decoding of a word, corresponding to a bit sequence, received over a noisy channel, which word prior to transmission over said noisy channel was a codeword according to a linear block code (LBC).

### BACKGROUND

Forward-error correction is used with many different communication systems, for example but not limited to wireless communication networks, such as telecommunication networks.

Linear block codes (LBC) are among the most theoretically studied families of codes. Within this family, low density parity-check (LDPC) codes are used in many wireless standards, including 5G and Wi-Fi. Message passing, also known as belief propagation, decoding is the usual method to decode LDPC codes. Decoding techniques have traditionally been codeword-centric: once a word is received, the decoding algorithm tries to find a codeword that is close to the received word following an approximate maximum likelihood criterion via message passing.

Another decoding strategy, which is noise-centric, has been recently proposed. It may be referred to as “Guessing random additive noise decoding”, abbreviated GRAND, and aims to find the noise sequence introduced by the channel instead of operating on the received word directly. GRAND was originally described for binary additive noise channels, but the main principle applies also to noise additive channels in general and there is also extension to real- and complex-valued channels. In its most general form, GRAND can be applied to any code.

GRAND and solutions based on it have e.g. been described in U.S. Ser. No. 10/608,672 B2, U.S. Ser. No. 10/608,673 B2, US 2020/0186172 A1 and K. R. Duffy, J. Li, M. Médard, “Capacity-Achieving Guessing Random Additive Noise Decoding”, IEEE Transactions on Information Theory 65 (7), 4023-4040, 2019.

GRAND as disclosed in the prior art can be described as comprising three parts:
A noise guesser: This component outputs candidate noise sequences.
A buffer with candidate words: This component stores a multiplicity of candidate codewords. A candidate codeword is the received symbol sequence, called word, minus the noise sequence generated by the noise guesser.
A code membership function: This component is needed to check if candidate codewords are codewords.

GRAND has also been disclosed with an abandonment rule, which is based on reaching a threshold on the number of candidate noise sequences that have been tested. In fact, it is unfeasible to check all noise sequences, since their number is exponential in the codeword length. Therefore, after guessing a predetermined number of noise sequences, the decoding is stopped regardless of whether or not one or more codewords are found.

The complexity of GRAND is deterministic. The performance of GRAND approaches maximum likelihood in the limit of large number of guesses, and it has been shown that the abandonment strategy, if not too restrictive, has immaterial impact on performance.

Further, GRAND is typically assumed to operate at very low channel error probability. In particular, for a binary symmetric channel, the average number of errors per word is assumed to be a small integer. In simulation results disclosed in the prior art, the small integer is at most 1.

### SUMMARY

In view of the above, an object is to enable or provide one or more improvements or alternatives in relation to the prior art, such as provide improvements regarding forward error correction based on GRAND.

According to a first aspect of embodiments herein, the object is achieved by a method, performed by one or more apparatuses, for supporting forward error correction, FEC, decoding of a word, corresponding to a bit sequence, received over a noisy channel. Prior to transmission over said noisy channel, said word was a codeword according to a linear block code, LBC. Said apparatus(s) obtains a parity check matrix associated with the LBC and receives said word. The apparatus(s) computes the syndrome for the received word using the obtained parity check matrix. Further, the apparatus(s) generate one or more noise sequences to affect bits of the received word that are in one or more bit positions identified through parity check equations of the obtained parity check matrix that the computed syndrome for the received word identifies as erroneous parity check equations. Moreover, the apparatus(s) form candidate codewords for said noise sequences, respectively. Each candidate codeword corresponding to the received word with removal of noise according to a respective one of said noise sequences. Furthermore, the apparatus(s) determines if any one of said formed candidate codewords is an actual codeword according to said LBC by computing the syndrome for the candidate codeword using the obtained parity check matrix.

According to a second aspect of embodiments herein, the object is achieved by a computer program comprising instructions that when executed by one or more processors causes said one or more apparatuses to perform the method according to the first aspect.

According to a third aspect of embodiments herein, the object is achieved by a carrier comprising the computer program according to the second aspect.

According to a fourth aspect of embodiments herein, the object is achieved by one or more apparatuses for supporting forward error correction, FEC, decoding of a word, corresponding to a bit sequence, received over a noisy channel. Said word was a codeword according to a linear block code, LBC, prior to transmission over said noisy channel. Said apparatus(s) is configured to obtain a parity check matrix associated with the LBC and to receive said word. The apparatus(s) is also configured to compute the syndrome for the received word using the obtained parity check matrix. Further, the apparatus(s) is configured to generate one or more noise sequences to affect bits of the received word that are in one or more bit positions identified through parity check equations of the obtained parity check matrix that the computed syndrome for the received word identifies as erroneous parity check equations. Moreover, the apparatus(s) is configured to form candidate codewords for said noise sequences, respectively. Each candidate codeword corresponding to the received word with removal of noise according to a respective one of said noise sequences. Furthermore, the apparatus(s) is configured to determine if any one of said formed candidate codewords is an actual codeword according to said LBC by computing the syndrome for the candidate codeword using the obtained parity check matrix.

The syndrome, when there are errors to correct, is non-zero and identifies rows of the parity check matrix that corresponds to parity check equations that are in error, i.e. are erroneous parity check equations. Further, these erroneous parity check equations will identify which bit positions of the word, corresponding to columns of the parity check matrix, that are involved and potentially caused the parity check equations to be in error. These bit positions are typically fewer than all bit positions of the word and will thus reduce the number of possible noise sequences that may have resulted in the error. Hence a reduced amount of noise sequences to guess from and to use to form candidate codewords in the next action is accomplished and an improvement over conventional GRAND based methods.

### BRIEF DESCRIPTION OF THE DRAWINGS

Examples of embodiments herein are described in more detail with reference to the appended schematic drawings, which are briefly described in the following.

FIGS. 1A-B are schematic illustrations of a parity check matrix in a first and second example with intersection and union sets.

FIGS. 2A-C are flowcharts schematically illustrating actions of an example method and example actions based on embodiments herein.

FIG. 3 is a block diagram schematically depicting functional blocks that may be considered for implementing a method based on embodiments herein.

FIG. 4 is a block diagram schematically depicting a system in relation to which embodiments herein may be implemented.

FIG. 5 is a flowchart schematically illustrating embodiments of a method according to embodiments herein.

FIG. 6 is a schematic block diagram for illustrating embodiments of how one or more apparatuses may be configured to perform the method and actions discussed in connection with FIG. 5

FIG. 7 is a schematic drawing illustrating some embodiments relating to computer program(s) and carriers thereof to cause an apparatus(es) to perform the method and related actions.

### DETAILED DESCRIPTION

Throughout the following description similar reference numerals may be used to denote similar elements, units, modules, circuits, nodes, parts, items or features, when applicable. Features that appear only in some embodiments are, when embodiments are illustrated in a figure, typically indicated by dashed lines.

Embodiments herein are illustrated by exemplary embodiments. It should be noted that these embodiments are not necessarily mutually exclusive. Components from one embodiment may be tacitly assumed to be present in another embodiment and it will be obvious to a person skilled in the art how those components may be used in the other exemplary embodiments.

As part of the development of embodiments herein, the situation indicated in the Background will first be further elaborated upon.

In GRAND, the maximum noise variance that is allowed before incurring in excessive computational demand is very low. This is so because if there are often error sequences with large Hamming weight, all sequences with lower Hamming weight need to be tested before catching the right one. Suppose, for example, that the errors occurred in a particular instance of the channel are 4, i.e., 4 bits have been flipped, and that the word length is n. Before discovering the right sequence of errors, all noise sequences with Hamming weight 1, which are n; and sequences with Hamming weight 2, which are (₂ⁿ)˜n²; and sequences with Hamming weight 3, which are (₃ⁿ)˜n³, have to be tested. Even for short codes, say n=128, such a number would be ≈350×10³. After testing a certain number of sequences without success, there would be abandonment of further attempts using the method and an error be declared.

In order to quantify for what kind of channels such abandonment rate is not too high, the word length is fixed to n and the flip probability to f. The number of flips (errors) is a Binomial random variable with n trials each with probability of success f. If fn=λ is relatively small, then the Binomial distribution is approximately a Poisson distribution with rate λ. The tail probability of having more than k errors is given by

$${p}_{k} ( λ ) := P [ Pois ( λ ) > k ] = 1 - {e}^{- λ} {\sum }_{i = 0}^{k} \text{?} \qquad Eq . 1$$

$$\text{?} \text{indicates text missing or illegible when filed}$$

Numerically, if λ=1, then p₃(1)≈0.08, p₄(1)≈0.019, etc. In GRAND, λ may be assumed to be even smaller than unity, e.g., λ=0.1. In this case, p₃(0.1)≈1.5×10⁻⁴ p₄(0.1)≈3.8×10⁻⁶, etc. Operationally, pₖ(λ) is a lower bound on the error probability. For example, if sequences up to 3 errors are tried and λ=0.1, it is declared an error with probability at least p₃(0.1)≈1.5×10⁻⁴. For such small λ to hold, either the channel does not introduce many errors, or the word length is small, or both. In practice, suppose a short code is used, such that n=128. Then, in order for λ=1 and λ=0.1 to hold, one needs f≈7.8×10⁻³ and f≈7.8×10⁻⁴, respectively. For longer codes, these flip probabilities need to be even smaller. Operationally, such low flip probabilities mean that the signal, after demodulation, appears with very high SNR.

For a random linear code of length n, rate R, and a channel with flip probability f, it can be observed that the number of typical noise sequences would be 2^{nH(f)}, where H(f)=−f log₂f−(1−f)log₂(1−f) is the binary entropy. A key takeaway here is that such a quantity is exponential in n and thus abandonment is typically needed unless/is so small that it is manageable to guess all typical noise sequences. This depends on the channel.

Although GRAND as such is applicable to any block code, the considerations above show that it may be desirable to apply GRAND only on channels with very high SNR and using relatively short codes.

Three major areas for improvement has been identified for conventional GRAND:
As explained above, for GRAND to be computationally feasible, the number of errors introduced by the channel needs to be small in absolute value, namely not only the fraction of errors per word needs to be small, but also the number of errors. With two or more errors, existing GRAND becomes computationally unfeasible.
Methods to guess and apply noise sequences and abandonment decisions are suboptimal. For example, many noise sequences are assumed to be equally likely with their order only being based on the Hamming weight, which is suboptimal. Also, disclosed abandonment strategies are only based on the number of guesses, which is suboptimal as well.

For conventional syndrome decoding with lookup table, its size is exponential in the number of checks, and therefore not feasible for practical codes. Furthermore, since the lookup table needs to be precomputed, this is not a flexible method for decoding codes with variable rates and/or punctured variable nodes.

Embodiments herein, explained in detail further below, and advantages thereof relate to:
More efficient guessing and application of noise sequences than in conventional GRAND, without reduced performance. Guessing of noise sequences can e.g. be made from a smaller number of noise sequences. Embodiments herein may be considered based on an observation that, for a fixed Hamming weight of the noise sequence, some of the noise sequences can be excluded as long as the decoder knows the parity-check matrix of the LBC being used, which typically is a necessary condition for decoding. In the case of only a single error, the right noise sequence can be generated and the right codeword immediately be decoded without generation and testing of several noise sequences.
More efficient abandonment strategies than for conventional GRAND, not only based on testing noise sequences up to a certain number of tests. The abandonment strategies may be considered code-specific, where the parity-check matrix for the LBC used and the received word are used to compute the syndrome for the received word, and from it the cardinality of some subsets of variable nodes that may be the one(s) in error. In the case of more than one error, it can be estimated how many guesses are needed in average to decode the received word correctly. Based on this number, it can be determined to abandon, i.e. not to proceed with GRAND, and instead e.g. pass the received word to another decoder, e.g. a normal message passing decoder.

Further, embodiments herein allow for parallel implementation as further explained below. This differs from message passing decoding that can be parallelized but only to a lower extent since message passing iterations are inherently sequential in nature. In particular, batches of noise sequences with cardinality equal to the number of concurrent threads, that the parallel hardware at hand is capable of running. can be tested in parallel. In practical implementations with GPUs or modern microprocessors, such a number of threads can be in the order of tens of thousands.

Moreover, as further described below, machine learning may advantageously be utilized in implementation of embodiments herein, in particular regarding abandonment.

Before discussing and exemplifying embodiment herein in further detail, some basic principles underlying embodiments herein will be discussed.

As already indicated above, when taking into consideration the structure of a linear block code being used, represented by its parity-check matrix, the number of noise sequences in a GRAND based method can be reduced because the structure of the code will remove some possibilities. In other words, the number of relevant noise sequences for a received word can be reduced based on the parity check matrix for the LBC code used.

Errors in the received word will cause one or more parity check equations to be in error. Using the parity check matrix to compute the syndrome for the received word will, in case or error(s), and thus a non-zero syndrome, identify one or more parity check equations (corresponding to rows) of the parity check matrix that that are erroneous parity check equations for the received word. As should be recognized by the skilled person, an erroneous check equation is a check equation that when applied to the received word, i.e. when used to check the received word, indicates that there is one or more errors in the variables checked by the equation. As also recognized by the skilled person, the variables of a check equation have correspondence with the bit positions of the checked word, respectively. In other words, each check equation has a subset of variables, corresponding to bit positions, that the check equation operates on. Such set of variables for a check equation may be named the support set of that equation.

Moreover, as known by the skilled person, a computed non-zero syndrome for a received word (which is computed using the parity check matrix for the LBC that the word was coded with prior to transmission), indicate which rows of the parity check matrix that correspond to erroneous check equations for the received word. The computed syndrome for a word corresponds to a vector with the same number of elements as there are rows of the parity check matrix. For example, a non-zero element, such as a ‘1’, in a certain position of this vector indicates that the row at this position of the parity check matrix corresponds to an erroneous check equation for the word. If the syndrome is computed for a word and the result is zero, there is no detectable error, and the word is a codeword.

To utilize the structure of the LBC being used, the syndrome of a received word is computed using the parity check matrix. This will, as explained above, identify which, if any, check equations that are erroneous. It will be assumed that there are one or more check equations that are erroneous since if the received word is already a codeword there is no need for error correction, apply GRAND etc.

Hence, the computed syndrome will identify one or several check equations, corresponding to rows of the parity check matrix, that are erroneous.

Information from these erroneous check equations can then be utilized to generate noise sequences with greater possibility than conventional GRAND to result in candidate codewords that are actual codewords. A noise sequence indicates which bit positions that are affected by the noise and may correspond to a bit sequence with non-zero elements, e.g. ‘1’s, in positions affected by the noise and that thus shall be flipped to form a candidate codeword. Hence, it is of interest to find and prioritize noise sequences that are relevant to try, and thereby which bits to flip, and preferably try noise sequences with greater probability to result in the actual codeword before noise sequences with lower such probability.

As realized from the above, each erroneous check equation identifies a subset of variables, i.e. the support set of that equation, where each variable corresponds to a bit position of the checked word.

According to some embodiment herein, the intersection and/or union of the support sets for the erroneous check equation are considered.

For example, the intersection set for two check equations consists of the variables that appear in both check equations. For more than two check equations, the intersection set consists of variables that appear in all check equations.

The union set for two check equations consists of all the variables that appear in the check equations. For more than two check equations, the union set consists of all the variables that appear in the check equations.

For a single channel error, all erroneous check equations must have a single common bit, and hence the error must be in the intersection of the support sets of the check equations. For multiple errors, the errors must be in the union of the support sets for the variables in error.

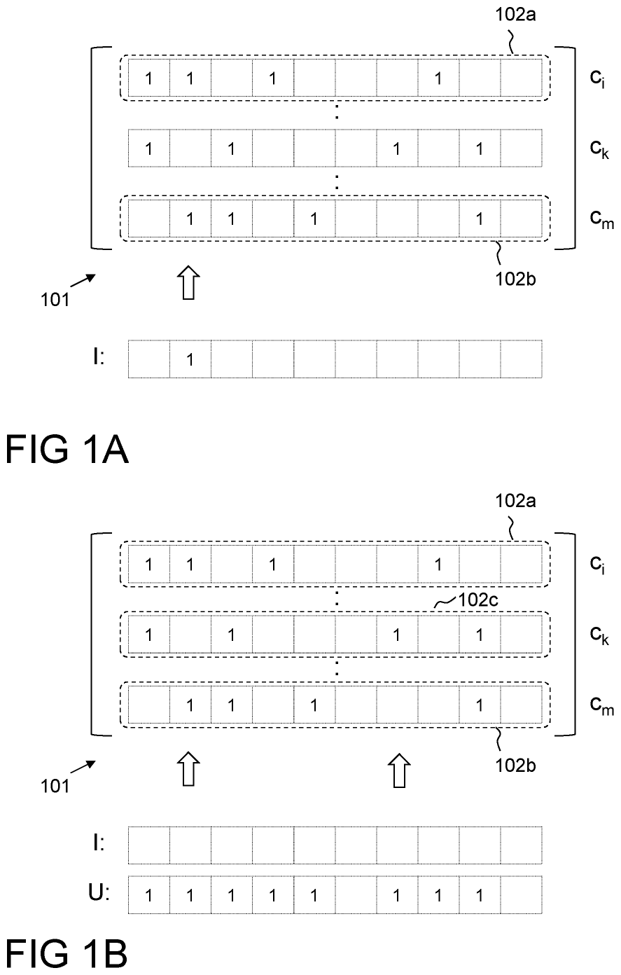

FIG. 1A is a schematic illustration of a parity check matrix H, in the figure indicated by reference numeral 101, that will be used in a first example to among other things explain the intersection set mentioned above. Columns of the parity check matrix 101 map to variables (bits) of a word to be checked by the parity check matrix, and rows correspond to parity check equations. In the figure only three rows and parity check equations are shown, ci, ck and cm. Further, the shown parity check matrix contains binary values, one bit per position. Only positions with ‘1’s are explicitly shown in the figure. The other positions that are shown empty in the figure actually contain ‘0’s. Assume that a single variable, i.e. bit, of a received word, and in the position indicated by the arrow, is received in error. This means that check equations ci and cm will be in error, i.e. are erroneous check equations, since these perform checks involving this bit position. As recognized by the skilled person, the erroneous check equations can be identified by computing the syndrome s for the received word using the parity check matrix. The erroneous check equations in this example are thus the ones indicated by 102a-b in the figure. For 102a. and thus an error in ci, this means that any of the variables participating in ci, identified by the positions of the ‘1’s, may be in error. Similarly, for 102b and thus with an error in cm, any of the variables participating in cm, identified by the positions of the ‘1’s in 101b, may be in error. The intersection set, which is named “I” in examples herein, is thus the set of variables involved in all of the erroneous check equations, here 101a-b, i.e. both ci and cm. The resulting intersection set I is schematically shown below the parity check matrix 101 in FIG. 1A. As expected, with the assumption of a single error in the position indicated by the arrow in the figure, the intersection set identifies the bit position of the error in the received word. The intersection set here only contains a single variable. For a single-variable error, the intersection set is non-empty. The single variable indicates that the error is in the bit position of the received word that corresponds to this variable. A noise sequence that affects only this bit position can thus be used to form a candidate codeword simply by flipping this bit of the received word. The result should then be codeword according to the LBC used and for which codeword the syndrome should be zero. This codeword thus corresponds to a forward error corrected version of the received word.

In many practical situation with low bit error probability the greatest error probability is a single error and hence the above procedure enable very efficient error correction.

FIG. 1B is a another schematic illustration with the parity check matrix 101 in another, second example to, among other things, explain the union set mentioned above for a situation with multiple errors. Focus will be on differences compared to the first example discussed above in relation to FIG. 1A. Assume for the present example that two variables, i.e. two bits, of a received word, in the positions indicated by the arrows, are received in error, i.e. the multiple errors are two errors in the example. This means that all shown check equations ci, ck and cm will be in error, i.e. are erroneous check equations, since these perform checks involving these bit positions. The erroneous check equations in this example are thus the ones indicated by 102a-c in the figure. For 102a and thus an error in ci this means that any of the variables participating in ci, identified by the positions of the ‘1’s, may be in error. Similarly, for 102b and 102c and thus with an error in cm and ck, respectively, any of the variables participating in respective cm and ck, identified by the positions of the ‘1’s in respective one of 101b-c, may be in error. The intersection set, which is named “I” is here zero since there in this example is no position where all erroneous check equations 102a-c perform checks. No structural information can directly be used from the intersection set I to generate noise sequences, although the empty set indirectly indicates that multiple errors are expected. Note that it is conceivable that multiple errors also can result in a non-empty intersection set. Hence an empty intersection set indicates multiple errors, but multiple errors do not always result in an empty intersection set.

The union, or fusion, set, which is named U, provides some further useful information. This set is the set of variables involved in all of the erroneous check 102a-c, i.e. in one or more of ci, ck and cm. In the shown example, the variables indicated by ‘1’ in the erroneous check equation 101a-c, i.e. in the example a total of 8 variables out of 10 possible. Noise sequences that affect these variables have the potential to form a candidate codeword that is an actual codeword and thus corresponds to a corrected version of the received word. There is no need to generate noise sequences that affect the two variables not part of the union set, i.e. that are not checked by the erroneous check equations. Hence, instead of guessing noise sequences that can affect all 10 bits, it suffice to guess noise sequences that can affect said 8 bits and e.g. starting with flipping 2 bits in different combinations if a situation of multiple bit errors has been identified or is expected, and when few bit errors are more likely than many bit errors.

A method based on embodiments herein may in short be described by the following actions:
1. A word is received after transmission over a channel that may have introduced errors, i.e. over a noisy channel. Prior to transmission the word was coded according to a LBC.
2. The syndrome s is computed for the received word using the parity check matrix of the LBC used for coding of the word.
3. Is s=0? If yes, a codeword was received (no detectable error), can be returned and the method end. Otherwise continue.
4. The intersection set I is computed for the variables in affected checks, i.e. in erroneous check equations (parity check matrix rows) as identified by the non-zero syndrome s.
5. Is the intersection empty? If yes, it can be concluded that more than one error occurred and it can be continue with action 6. Otherwise, flip bit(s) of the received word that correspond to the variables involved in the in intersection set I and compute syndrome s until a codeword if found, if any. If a codeword is found, the codeword can be returned and the method end. If no codeword is found, continue with action 6.
6. The union set U is computed for the variables in affected checks, i.e. in erroneous check equations (parity check matrix rows) as identified by the non-zero syndrome s.
7. Flip bit(s) of the received word that correspond to the variables involved in the in the union set U and compute syndrome s until either reaching a maximum number of attempts or a codeword is found. If a codeword is found it is returned and the method ends. If maximum number of tests reached, the method is abandoned.

Based on the structure of the specific code used, i.e. LBC, the syndrome s identifies erroneous check equations in the parity check matrix and thereby reveals information about errors in the variable nodes. Only looking at the weight of the syndrome will not tell the whole story, but offers a possibility to abandon decoding using GRAND, e.g. if the weight indicates so many bit errors that GRAND is considered unsuitable to apply.

A method based on embodiments herein, e.g. as described above, have at least four different places where abandonment checks can be performed:
When the weight of the syndrome is above a threshold.
When the cardinality of the intersection set is either zero or above a threshold.
When the cardinality of the union set is above a threshold.
When the number of tests is above a threshold.

Example A: For a regular LDPC code with variable degree dv and check degree dc, the maximum number of variables affected by a single error is 1+(dc−1)dv when embodiments herein are applied. If q errors occur then the number of affected variables are ≤q[1+(dc−1)dv] with equality if none of the variables in the union sets of the individual errors are common. Hence, for a (3,6) regular LDPC code, the maximum number variables affected by a 1-error pattern is [1+(6−1)*3]=16, and a 2-error pattern 2[1+(6-1)*3]=32. For a 1,000-bit codeword length and a 2-error pattern, this means a reduction from 499,400 noise pattern candidates to 496 by application of embodiments herein.

Example B: Consider a (128,64)-CCSDS code. For single error patterns, only one flip per word is needed when applying embodiments herein instead of 128/2 flips if conventional GRAND is applied. For two-error patterns, an average of 1,244 guesses is necessary, instead of 128+{128 choose 2}/2=4, 192 guesses with conventional GRAND. By “{n choose k” } is meant. For three-error patterns, about 50,000 guesses are needed instead of 128+{128 choose 2}+{128 choose 3}/2≈178,944 guesses with conventional GRAND. For four-error patterns, about 1.4 million guesses are necessary instead of 128+{128 choose 2}+{128 choose 3}+{128 choose 4}/2≈5.68 million guesses with the conventional GRAND. For single error, the saving factor in terms of guesses, and in turn computations, is 128×. In all other cases, the saving factor is about 7×, that is, about 14% of the computations are still needed and about 86% can be avoided thanks to embodiments herein. It should be highlighted that the case of single error can be expected to be the most common one in many practical situations, and that GRAND is designed to be used at high SNR. Using the same examples as at the beginning of this section, if the flip probability f is such that λ=nf=0.1, then the probability of no error is e^{-λ}≈0.9, in which case we receive a codeword; the probability of a single error is equal to e^{-λ}λ=0.09, in which case the saving is equal to 128×; in the remaining=1% of the cases, the saving is equal to about 7×. Therefore, the average saving is much higher than 7×.

TABLE 1

| Number | | |
|---|---|---|
| of | Conventional | Embodiments |
| errors | GRAND | herein |
| 1 | 64 | 1 |
| 2 | 4,192 | 1,244 |
| 3 | 178,944 | ≈50,000 |
| 4 | ≈5.68 million | ≈1.4 million |

Table 1 above provides an overview of the comparison between conventional GRAND and application of said method based on embodiments herein, in terms of number of guesses required in average for said (128, 64)-CCSDS code, which is a representative example of a short LBC.

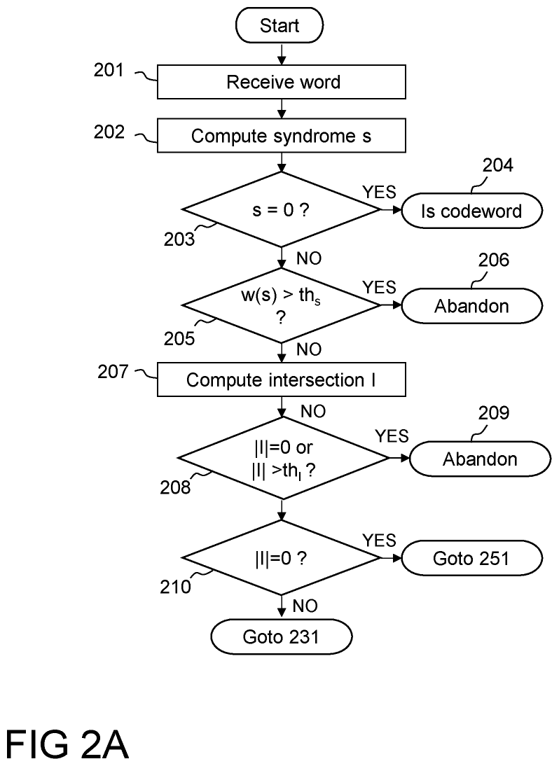

FIGS. 2A-C are flowcharts schematically illustrating actions of an example method and example actions based on embodiments herein. The method can be considered a more detailed variant and example of the method shortly described above in relation to actions 1-7. Actions below may be taken in any suitable order and/or be carried out fully or partly overlapping in time when this is possible and suitable.

### Action 201

A word, e.g. a word y, is received over a communication channel, e.g. a channel used for wireless communication, and that may have introduced one more errors, i.e. the received word may be corrupted by noise. Prior to transmission over the channel, and thus before said corruption by noise, the word was a codeword according to a LBC that typically is predetermined.

### Action 202

The syndrome s is computed for the received word, where s=Hy^{T} with H being the parity check matrix and T denoting the transpose. The parity check matrix is given by the LDC used and is thus also typically predetermined. The syndrome s is a vector with as many elements are there are parity checks in the code, and thus one element per parity check equation. A non-zero element indicates that the corresponding check equation is in error. For binary codes, only odd number of errors can be detected by a single equation, since all even numbers are 0 modulo 2. Hence a check equation in error indicates that an odd number of bits are in error in that particular equation.

### Acton 203

If the syndrome s=0, then the received word y is a codeword according to the LBC used in the FEC and the decoding is done, i.e. in this case by identification that the received word contained no error and was a codeword, and the method proceeds with Action 204 below

If on the other hand the syndrome s is non-zero, the received word contains error(s), i.e. the transmitted codeword was corrupted by noise during transmission over the channel and the received word is not a codeword. The decoding will thus proceed in an attempt to find the codeword that was corrupted and thereby correct the received word, and the method proceeds with Action 205.

### Action 204

The identified codeword may be output to be further processed by higher layers and/or other functionality.

### Action 205

This action is a part of such abandonment procedures as indicated above, which also will be further discussed below. Here, if the Hamming weight, i.e. number of ones, of the syndrome exceeds a threshold th_{S}, then it may be deemed likely that more channel errors than the decoding algorithm is capable of handling, or be able to handle with sufficient performance, have occurred and the decoding is abandoned, see Action 206.

The skilled person is able to estimate and/or perform routine testing to determine a suitable value for th_{S}. What is suitable may differ depending on situation and may also depend on requirements and available hardware/software for implementation. The threshold th_{S} may thus be predetermined or predefined when performing the method.

If not abandoned, the method proceeds with Action 207.

### Action 206

In case of abandonment the received word y may be forwarded to a message passing decoder, retransmission may be requested and/or an error may be declared to higher layers.

### Action 207

For each check equation in error there is a set of variables that participate in that check equation. The intersection I of those sets are computed, e.g. as explained above in connection with FIG. 1A. For a single error, that error must affect all the check equations that are erroneous and hence the intersection must be non-empty. If multiple channel errors occur, the intersection can be empty. Hence if I is an empty set, then either zero or more than 1 error has occurred. Zero error has already been checked for above, and hence it would here mean multiple errors. Since it, as explained above, in many situations of practical interest may be assumed that the number of channel errors is low, or that lower number of errors is more likely than higher number of errors, it may be assumed that if the intersection I is non-empty, then a single channel error has occurred.

### Action 208

This action is also part and example of such abandonment procedures as indicated above, and further discussed below. If the intersection is empty or above a certain threshold th_{L} it can be chosen to abandon the decoding, see Action 209, e.g. since this may indicate more than one error. Note that in some situations, there is no abandonment even if the intersection I is empty but other actions take part, see e.g. Action 210 below.

In general it is optional to apply any abandonment procedure herein, even though they may be beneficial to apply to thereby be able to avoid situations where GRAND and/or some embodiments herein are not well suited to apply or continue to apply, e.g. where they unlikely, or not within a reasonable time, will be able to find the codeword.

### Action 209

This action, i.e. abandonment of the method, and subsequent actions, if any, can be same or similar as described above for Action 206.

### Action 210

It is checked if the Intersection set I is non-empty or not and depending on the result the method proceeds with different action. For example, if the intersection set I is non-empty the method proceeds with Action 231 etc, as shown in FIG. 2B and further described below, and if it is empty, the method proceeds with Action 251 etc. as shown in FIG. 2c and described below.

### Action 231

This action is start of a “loop” outlined by the dashed box 230, where for each one of variable(s) in the (non-empty) intersection set I, a sequence of actions described next are performed.

### Acton 232

The bit corresponding to the variable is flipped for the received word, i.e. change its value from 0 to 1 or from 1 to 0. As should be realized, this corresponds to generating a noise sequence and removing the noise according to this noise sequence from the received word, thus forming a candidate word y′.

### Action 233

The syndrome s′=Hy′^{T} is computed, i.e. the syndrome for the candidate word y′.

### Action 234

It is checked if the computed syndrome s′ is empty or not. If it is empty, the method proceeds with Action 235, and if it is not empty, the method proceeds with Action 237.

### Action 235

If the computed syndrome s′ is empty the candidate codeword is an actual codeword, the decoding was thus successful and the method can end. The identified codeword may be output to be further processed by higher layers and/or other functionality, i.e. similar as for Action 204 above.

Note that for LDPC codes it is not uncommon that the intersection set I has cardinality 1 and there is only one variable that can be in error. In those cases, the decoding amounts to finding the one bit in error and correct it, such as in the present action.

### Action 236

When the syndrome s′ is non-empty i.e. s′≠0, it may be assumed that candidate codeword was no actual codeword, and hence that the flipped bit did not result in correction. The flipped bit of the received word may thus be reset to its original value. If more variables remain in the intersection set I, e.g. if there were more than one variable involved in the intersection, then the loop 230 is performed again for the next variable, that is, a bit flipped for this variable in Action 232 etc.

When all variables in the intersection set I have been checked etc. as described above without forming of a candidate codeword that is an actual codeword according to its syndrome, the method proceeds with Action 251 etc. as shown in FIG. 2c and described next.

### Action 251

This action can be reached from Action 210 or 236. Hence, if the intersection set I is empty or it was not possible to find the actual codeword for a single error by utilizing the computed intersection set I, the union set U is computed for the variables involved in the check equations in error, e.g. as explained above in relation to FIG. 1B.

### Action 252

This action is also part and example of such abandonment procedures as indicated above, and further discussed below. If the cardinality of the union set, u=|U|, exceeds a certain threshold th_{U} the decoding can be abandoned, i.e. similar as for example described above, such as in relation to Action 206. Since it will now have to be flipped 2 or more bits, or in other words, noise sequences involving 2 or more bits are to be generated, the number of combinations to test will grow quickly as the cardinality of U increases. Hence, this is a very reasonable place in the method to decide regarding abandonment, independent on if any of the previous abandonment decision have been applied or not. The number of ways to select j items, here variables that map to bits to flip, from a set of u items is given by the binomial coefficient “u-choose-j”. Hence, as u increases and j increases, the number of guesses will very quickly increase. However, since u<n, where n is the codeword length, this number still grows significantly slower than guessing from all possible patterns. Also, by exploiting that the noise guessing is parallelizable, it can be tolerated a larger number than without parallelization, but there is still a limit to how large values u and j are reasonable to handle, which is a reason for the abandonment decision at this point.

### Action 253

Similar as for Action 206, in case of abandonment, the received word y may be forwarded to a message passing decoder, retransmission may be requested and/or an error may be declared to higher layers.

### Action 255

This action is start of a “loop” outlined by the dashed box 254, where for each error pattern, corresponding to noise sequence, with weight j, starting with weight j=2, attempt is made for finding a noise sequence with this weight in the computed union set U and that results in a candidate codeword that is an actual codeword, as further described by the following actions. Or in other words find an error patter of Hamming weight j in the union set U that can be used to flip bits of the received word so it becomes an actual codeword. It is thus started to guessing noise sequence, also known as error patterns, of weight 2, and then, if no codeword has been found, progress to successively larger weights. Starting with an assumption that there is a low number of errors is of course advantageous when low amounts of errors are more likely than higher amounts.

### Action 256

For the given Hamming weight j, e.g. 2 to begin with, all possible such noise sequences from the union set U may be generated and tested, which may be described as generating all j-tuples selected from the set U and if no codeword is found based on this, j is increased, e.g. to 3, and the procedure repeated. This is further explained in the actions below. The number of guesses that can be needed per j-tuple, i.e. noise sequences to generate and test to see if any can results in an actual codeword, can be determined according to “j-choose-k”.

### Action 257

For each guessed, thus generated, noise sequence, the j bits in the received word y corresponding to the pattern being guessed are flipped. This corresponds to flipping the bits corresponding to the variables involved in the noise sequence, i.e. error pattern, that have been guessed. Flipping is the same procedure as indicated above, i.e. change value from 0 to 1 or from 1 to 0. As should be realized, this corresponds to generating a noise sequence and removing the noise according to this noise sequence from the received word, thus forming a candidate word y′ that then can be tested by computing its syndrome.

### Action 258

The syndrome s′=Hy′^{T} is computed, i.e. the syndrome for the candidate word y′, correspond to the received word y with flipped bits according to the noise sequence being tested.

### Action 259

It is checked if the computed syndrome is empty, i.e. if s′=0. If s′=0 then y′ is a codeword. That is, it is tested if the generated noise sequence resulted in a candidate codeword that is an (actual) codeword according to the LBC (and parity check matrix).

If s′≠0, then y′ is not a codeword, and y may be reset by flipping the bits that resulted in y′ flipped bits.

This action and the check as such corresponds to the one performed in Action 234 but for s′ instead of s.

### Action 260

If s′ is empty the candidate codeword was an actual codeword, the decoding was thus successful and the method can end. The identified codeword may be output to be further processed by higher layers and/or other functionality, i.e. similar as for Action 204 above.

### Action 261

It is checked if there are still patterns of j bits to test, i.e. if there are still new noise sequences to generate and test for the current j-bits noise sequences being tested, e.g. patterns of 2-bit noise sequences to begin with. Hence, if such new noise sequence is still left to test, bits according to it shall be flipped and Action 257 etc. be performed again but for the new sequence.

### Action 262

If on the other hand, all noise sequences for the present j have been tested, j is increased by one. In other words, if there are no further patterns of j bits to test, j is incremented by one.

### Acton 263

Since, as indicted above, there may be many tests if there are many bits with errors in the received word and GRAND based methods are not suitable with many bit errors, it may be suitable to apply a maximum of errors, i.e. maximum j. It is checked if j is above this limit, e.g. above a max_error value. This value may be predefined or predetermined when the method is performed, e.g. in practice be set in advance based on what maximum number of errors the method has been deemed suitable to handle given a practical situation and circumstances.

If the maximum umber of error has not been reached, Action 256 etc. is performed again for the new j.

### Action 264

If on the other hand, the maximum number of error has been reached, the method is abandoned. Similar as for Action 206, in case of abandonment, the received word y may be forwarded to a message passing decoder, retransmission may be requested and/or an error may be declared to higher layers.

In FIG. 2, the “abandon” actions may be interpreted as logical points where the algorithm can stop. However, it does not necessarily have to stop in any of such place. The guesses are independent and each noise sequence, i.e. error pattern, and actions when it is applied can be performed in parallel. Let e.g. T be the number of threads that a parallel hardware at hand can handle. Each thread may comprise a syndrome computation and check. Therefore, T noise sequences can be checked in parallel. The abandonment conditions can be checked at the end of each cycle of T checks.

Note that embodiments herein are not necessarily involving all actions of the example method above and exemplified in FIG. 2. As the skilled person realizes, some actions may be performed and be effective without other actions. For example: Only some or none of the abandonment procedure and actions above may be performed. It may only be performed actions based on the intersection set I, such as the action related to FIG. 2B and abandon the method instead of performing actions based on the union set U, such as the actions related to FIG. 2C. Alternatively, the actions based on the intersection set I may be skipped and it may be progressed directly with the actions based on the union set U with j starting with 1 instead of 2. In other words, the actions involving the intersection set are ignored and instead noise sequences, i.e. error patterns, are guessed and searched over the union set U starting with noise sequences of weight 1. The computational complexity for searching for a single error in the union set of cardinality u=|U| is u\hat{ }1=u, instead of |I|, where often |I|=1. The additional number of guesses and searches that may be needed can be negligible, and e.g. hardware and/or algorithmic savings may motivate this.

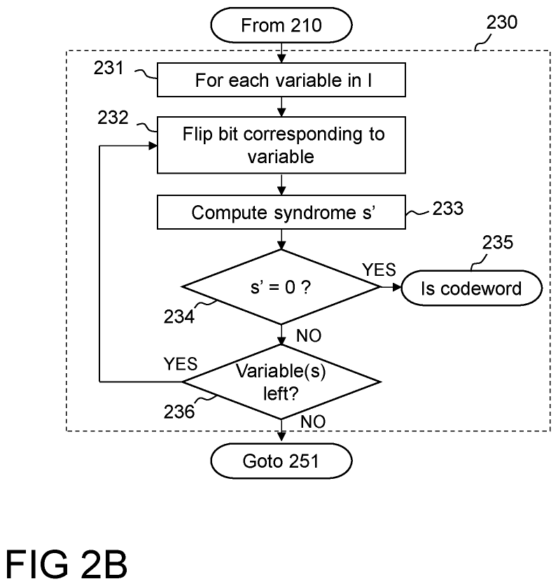

FIG. 3 is a block diagram schematically depicting functional blocks that may be considered for implementing a method based on embodiments herein, e.g. as described above, i.e. a method for FEC decoding of a received word based on a LBC. The shown blocks may be implemented in hardware and/or software. A word receiver 301 may receive a word and store the received word, i.e. the word to be decodes, e.g. corresponding to y above. A syndrome computer 302 may compute the syndrome, and corresponds to a membership function in GRAND since it, as explained above, is used to test noise sequences, i.e. to check if a candidate codeword formed is an actual codeword or not. A set computer 303 may compute the intersection set I and/or union set U. A noise guesser/sequence generator 303 may generate each noise sequence to be used to form a respective candidate codeword, i.e. that determines which bits of the received word to be affected, e.g. flipped, and thereby form the candidate codeword. A word modifier 305 may modify the received word and form the candidate codeword by subtracting the noise sequence from the received word, which in practice may be performed as exemplified above by flipping bits of the received word according to the noise sequence. The modified word, i.e. candidate codeword, may then be checked by the syndrome computer 302 to see if it is an actual codeword. A codeword outputter 306 may output the candidate codeword if the syndrome computer 302 found it to be an actual codeword. Note that the syndrome computer 302 is shown two times to make the figure more clear.

An abandonment monitor 306 may implement abandonment procedures(s) as described above and may use inputs from the syndrome computer 302, the set computer 303, and the noise guesser 304. An alternative decoder 308 is also shown and may be used in case of abandonment and/or if the method does not succeed in decoding the received word, i.e. does not succeed in finding the actual codeword. The alternative decoder 308 may be one suitable for decoding of a larger amount or errors. It may of course also be possible to let the alternative decoder 308 operate on the received word in parallel, i.e. simultaneously, with a method based on embodiments herein, e.g., in order to save time and then use the actual codeword first produced.

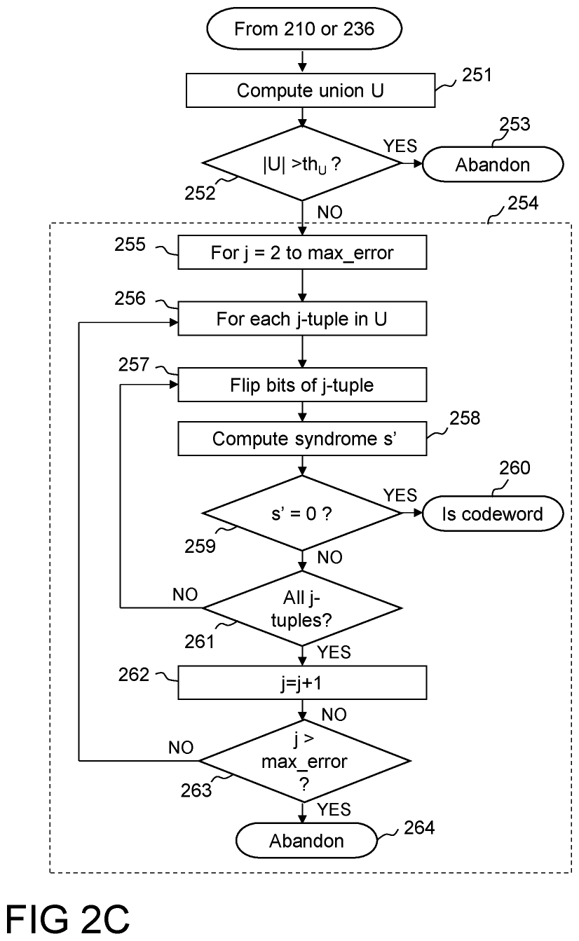

FIG. 4 is a block diagram schematically depicting a system 400, e.g. communication system or network, in relation to which embodiments herein may be implemented. The figure also shows apparatuses that may perform methods and actions relating to embodiment herein. A transmitting apparatus 420 is configured to transmit a word, i.e. bit sequence of certain length, over a channel 430 to a receiving apparatus 410 that is configured to receive such transmitted word. The channel is typically but not necessarily a wireless communication channel. Prior to transmission over the channel 430 the word is a codeword according to a linear block code, LBC. The channel introduces one or more errors in the transmitted word so the received word is no longer a codeword according to the LBC. It is thus desirable to forward error correct the received word, i.e. find the actual codeword that was transmitted, utilizing knowledge about the LBC used, e.g. by performing methods and actions based on embodiments herein. As realized by the skilled person, in practice the transmitting and receiving apparatuses 410, 420 may correspond to different types of devices. For example: a wireless device and a base station of a wireless communication network, such as a telecommunications network, two wireless devices, e.g. smart phones, that are communicating directly with each other, a computer communicating with a WiFi access point or directly with another computer, just to mention some examples.

The figure also shows a further apparatus 441 and a network 440, such as a communication or computer network. It is implied that a network, such as the network 440, comprises interconnected network nodes that may include the further apparatus 441 as indicated in the figure. The further apparatus 441 may thus be part of the network 440, i.e. be a network node thereof, or may be separate from it (although not indicated in the figure). The receiving apparatus 410 and/or the transmitting apparatus 420 may be part of the network 440, or may be part of another network, e.g. a wireless communication network, that is communicatively connected and/or supported by the network 440. The network 440 may correspond to the Internet or a local area network or a so called computer cloud, e.g. accessible via the Internet, and configured to perform methods and/or actions based on embodiments herein, e.g. as a service, and may thus operate on the word received by the receiving apparatus 410 and provided to the network 440 and/or further apparatus 441. The further apparatus may correspond to a server, or another device, e.g. network node, that is more suitable to perform methods and action based on embodiments herein than the receiving apparatus 410 as such, or be an apparatus to assist the receiving apparatus 410 in performance of some actions based on embodiments herein. Also the transmitting node 420 may be communicatively connected to the further apparatus and/or network 440, which may offer an additional way for communicating with the receiving apparatus 420, e.g. to exchange information using other communication channel(s), such as to exchange information on the LBC being used, such as information on the parity check matrix of the LBC. However, this is info that can be predetermined and be agreed and/or known in advance by also other means, e.g. via standardization.

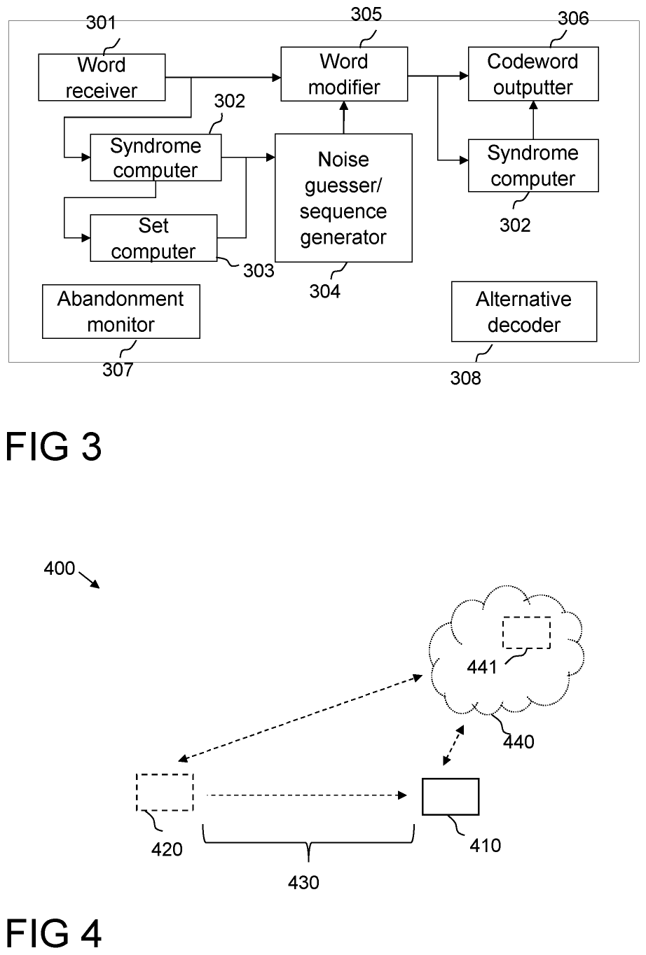

FIG. 5 is a flowchart schematically illustrating embodiments of a method according to embodiments herein. The method is for supporting forward error correction (FEC) decoding of a word, corresponding to a bit sequence, received over a noisy channel, e.g. the channel 430. Prior to transmission over said noisy channel the word was a codeword according to a linear block code (LBC). In other words the received word may be such as in the examples above, e.g. y. In general embodiments herein relate to FEC based on decoding of LBCs. The LBC may be a binary code, based on a binary alphabet, or a non-binary code. Embodiments herein may efficiently be used with low-density parity-check (LDPC) codes, but are not limited to such codes. Embodiments herein may be especially effective with LDPC codes. One reason is that there are few ‘1’s in the parity-check matrix for LDPC codes, therefore the intersection and union sets are smaller than those that would derive from a denser code affected by the same errors (bit flips). The general principle is that the lower the density, i.e., the less the number of ‘1’s), the better.

As already indicated above, the method may be performed by one or more apparatuses that e.g. may correspond to the receiving apparatus 410 and/or the further apparatus 441 and/or apparatuses corresponding to one or more network nodes of the network 440.

The actions below that may form the method may be taken in any suitable order and/or be carried out fully or partly overlapping in time when this is possible and suitable.

### Action 501

A parity check matrix associated with the LBC is obtained. That is, a parity check matrix for checking if a word is a codeword according to the LBC or not. The parity check matrix is typically predetermined, e.g. according a standard or other agreement regarding the LBC used. It is also possible to obtain the parity check matric by receiving it or information identifying it from the transmitting side e.g. via some other communication channel as indicated above.

### Action 502

Said word is received, i.e. the word that was received over the noisy channel is obtained or received by the apparatus(es) performing the method. In other words, the word may be received directly from the noisy channel when e.g. the receiving apparatus 410 are involved in performing the method or via the receiving apparatus 410 if the method is performed by other apparatus(es), e.g. the further apparatus 441 and/or apparatus(es) of the network 440.

This action may fully or partly correspond to Action 201.

### Action 503

The syndrome, e.g. s as in the example above, is computed for the received word using the obtained parity check matrix. The syndrome may be computed in any conventional way for computing the syndrome for a word using a parity check matrix for the LBC associated with the word.

This action may fully or partly correspond to Action 202.

### Action 504

It is generated one or more noise sequences to affect bits of the received word that are in one or more bit positions identified through parity check equations of the obtained parity check matrix that the computed syndrome for the received word identifies as erroneous parity check equations. As realized, this typically means that the syndrome is non-zero, and that there is one or more bits in error in the received word. As recognized by the skilled person, the syndrome identifies rows of the parity check matrix that corresponds to parity check equations that are in error, i.e. are erroneous parity check equations. Further, the erroneous parity check equations will identify which bit positions of the word, corresponding to columns of the parity check matrix, that are involved and potentially caused the parity check equations to be in error. These bit positions are typically fewer than all bit positions of the word and will thus reduce the number of possible noise sequences that may have resulted in the error. Hence a reduced amount of noise sequences to guess from and to use to form candidate codewords in the next action is accomplished.

In some embodiments, said one or more noise sequences are generated to specifically affect bits in one or more first bit positions of the received word. The first bit positions being all bit positions, if any, checked by all of said erroneous parity check equations. As should be realized, all bit positions, if any, that are checked by all of the erroneous parity check equations typically correspond to the bit positions identified by the intersection of those rows of the parity check matrix that correspond to the erroneous check equations. Hence, the intersection will only be non-empty for bit positions that are checked by all erroneous parity check equations. Or in other words, since the erroneous check equations correspond to certain rows of the parity check matrix, the intersection will only be non-empty at bit positions where all of these rows contain non-zero elements, e.g. ‘1’s. Said first bit positions may be identified by computing the intersection set I as in the example above.

In some embodiments, said one or more noise sequences are generated to specifically affect bits in one or more second bit positions of the received word. The second bit positions being all bit positions checked by at least one of said erroneous parity check equations.

As should be realized, all bit positions checked by at least one of the erroneous parity check equations typically correspond to the bit positions identified by the union of rows of the parity check matrix that correspond to the erroneous check equations. Hence, the union will be non-empty for all bit positions checked by at least one of the erroneous parity check equations. Or in other words, since the erroneous check equations correspond to certain rows of the parity check matrix, the intersection will be non-empty at bit positions where any of these rows contain nonzero elements, e.g. ‘1’s. For example, said second bit positions may be identified by computing the union set U as in the example above.

### Action 505

It is formed candidate codewords for said noise sequences, respectively. Each candidate codeword corresponding to the received word with removal of noise according to a respective one of said noise sequences. This procedure as such may be as in conventional GRAND.

### Action 506

It is determined if any one of said formed candidate codewords is an actual codeword according to said LBC. This is done by computing the syndrome for the candidate codeword using the obtained parity check matrix. Computing the syndrome as such may be performed as in Action 503 but here thus for a candidate codeword instead of the received word. The syndrome as such may be computed in any conventional manner. The difference compared to Action 503 is that the syndrome here is computed to check if any of potentially many candidate codewords is an actual codeword or not. Determine if a word is a codeword or not by computing the syndrome for the word to is as such a known procedure, where e.g. a zero syndrome means that the word is a codeword and a non-zero syndrome that it is not, as also have been explained above. If a candidate codeword is determined to be an actual codeword, the typical assumption is that the actual codeword corresponds to a corrected version of the received word.

Actions 504-506 above may fully or partly correspond to the actions in dashed boxes 230 and 254.

In some embodiments, said generating, forming and/or determining actions, i.e. Actions 504-506, regarding said noise sequences to specifically affect bits in said one or more first bit positions, are performed in response to that the number of first bit positions are below a certain first threshold number. As mentioned above under Action 504, the first bit positions may be found by computing said intersection. The first threshold number may relate to the threshold th_{I} in the above example. These embodiments thus relate to an abandonment procedure where the first threshold number can be used make sure that that the method is only performed when the number of first bit positions is below the first threshold number, which may be set to correlate with a sufficiently low number of errors to make it worthwhile to continue and perform the rest of the method. If not, it may be better to abandon the method and try something else that may be more suitable in case of many bit errors in the received word.

In some embodiments, said generating, forming and/or determining actions, i.e. Actions 504-506, regarding said noise sequences to specifically affect bits in said second bit positions are performed in response to that the number of second bit positions are below a certain second threshold number. As mentioned above under Action 504, the second bit positions may be found by computing said union. The second threshold number may relate to the threshold th_{U} in the above example. These embodiments thus relate to an abandonment procedure where the second threshold number can be used make sure that that the method is only performed when the number of second bit positions is below the second threshold number, which may be set, predefined or predetermined to correlate with a sufficiently low number of errors to make it worthwhile to continue and perform the rest of the method. If not, it may be better to abandon the method and try something else that may be more suitable in case of many bit errors in the received word.

In some embodiments, said generating, forming and/or determining actions, i.e. Actions 504-506, regarding said noise sequences to specifically affect bits in said second bit positions are performed in response to that no candidate codeword was determined to be an actual codeword for said noise sequences generated to specifically affect bits of the received word in said one or more first bit positions. This correspond to starting with noise sequences affecting said first bit positions, e.g. based on said intersection, and with only a single error, which enable very fast decoding, i.e. error correction, of a word with a single error. Only if this does not succeed, and it should be 2 or more errors, noise sequences affecting said second bit positions, e.g. based on said union, may be generated and used in attempts to decode and thereby be able to error correct the received word, i.e. find a candidate codeword that is an actual codeword.

Further, in some embodiments, said generating, forming and determining actions are performed in response to that the computed syndrome for the received word, as in Action 503, identifies no more than a certain number of erroneous parity check equations. These embodiments thus relate to another abandonment procedure. Said certain number of erroneous parity check equations may relate to the threshold th_{S} in the above example. No more than a certain number of erroneous parity check equations being identified by the syndrome corresponds to that the weight of the computed syndrome is not above a certain weight. Thanks to this, it can early, even before said other abandonment procedures may be applied, be made sure that actions involving generation of noise sequences etc, only are performed according to the method when it is expected that the method will be beneficial and/or efficient and/or useful to apply. Weight and number of erroneous parity check equations correlate with number of bit errors, and in case of too many bit errors, the method is typically not beneficial or efficient to apply and it may be better to abort and proceed according to some other method or procedure.

### Action 507

If a candidate codeword is determined to be an actual codeword, this actual codeword may be provided, e.g. output, for further processing where the information contained in the word is taken care of. The further processing may be performed by higher layers and/or another apparatus or device, which the actual codeword thus may be provided to, such as be sent to.

The above-mentioned threshold numbers and thresholds, e.g. th_{S}, th_{I} and th_{U} are, in general, dependent on the parity-check matrix that will be different from case to case where embodiments herein are applied. Machine learning can be used to find appropriate values for such thresholds, as an alternative or in addition to other ways, such as indicated above, to find suitable threshold values to apply. The following are two examples of how machine learning may be applied to this problem:
Offline learning: in a supervised learning fashion, a neural network may be trained to infer the probability that, given a current configuration, decoding would fail within a prefixed number of trials; or predict the number of necessary flips for successful decoding and then decide whether or not to perform decoding based on a threshold equal to the maximum number of trials that are allowed. The configuration can be the size of the sets described in the example above, i.e., syndrome, intersection set, and union set. Data is virtually infinite since Monte Carlo methods may be used to generate codewords and noise values.
Online learning: a reinforcement learning algorithm, such as State-action-reward-state-action (SARSA) or multi-armed bandit, can be used to predict the probability of correct abandonment or the number of necessary flips for successful decoding (through a value function) from a given configuration (state). The configuration can be the sets described above. The probability of correct abandonment is the complement of the probability that, after a fixed number of trials, given the current state, decoding would fail.

The machine learning components may here suitably be part of the “Abandonment monitor” block 307.

Another possible application of machine learning in implementation of embodiments herein is regarding the guessing, i.e., to determine which bits to flip. Here machine learning application may relate to the “Noise guesser/sequence generator” block 304. Noise may be assumed independent and identically distributed (i.i.d.) over the codeword. However, if noise presents patterns that are not i.i.d. over the codeword this can be learnt, and noise sequences be generated according to the pattern learnt, i.e., so that noise sequences with higher probability to result in a candidate codeword that is an actual codeword are generated before noise sequences with less probability to result in such. For example, the decoder may have side information in terms of a channel quality metric that can be used to infer the probability of each bit being flipped by the channel.

In examples herein it has sometimes been assumed a binary channel to simply explanation, but embodiments here are also applicable to continuous channels. For continuous channels, a log likelihood ratio (LLR) may be computed for the received word, e.g. in a demodulator that can be used as a soft decoder. For example, when it is referred to flipping bits and similar it is for referred to that 0 is changed to 1 and vice versa. For a continuous channel, bit flipping corresponds to a change of the sign of the LLR. The computation of the syndrome for a continuous channel also becomes different. For the binary channel the syndrome computations are typically done with modulo-2 arithmetic, whereas for the continuous channel the syndrome, which then can be regarded a soft syndrome, is computed using hyperbolic tangent and its inverse, as done in message passing decoding of LDPC codes, as known by the skilled person and in the prior art. Using a convention that a positive LLR value corresponds to a 0, it can be determined that the syndrome is all zero when the (soft) syndrome values are greater than zero.

Practical communication channels often experience fading, i.e. the instantaneous signal-to-noise ratio (SNR) varies over time. If the instantaneous channel SNR is low, then the probability of error is higher. Hence, when guessing noise, the noise guesser can be adapted to consider the instantaneous SNR. For example, it can be started to guess errors, i.e. noise sequences, at locations with low instantaneous SNR.

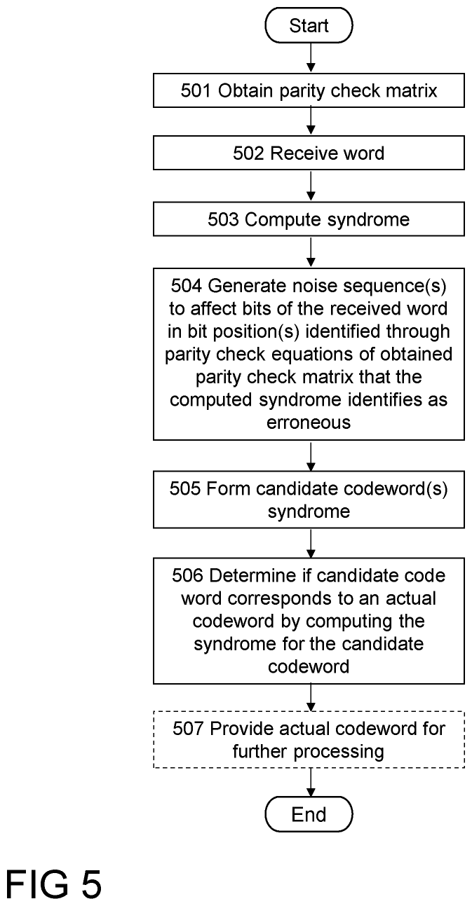

FIG. 6 is a schematic block diagram for illustrating embodiments of how one or more apparatuses 600 may be configured to perform the method and actions discussed above in connection with FIG. 5. The apparatus(es) 600 may correspond to the receiving apparatus 410 and/or the further apparatus 441 and/or one or more apparatuses of the network 440.

Hence, said apparatus(es) 600 is for supporting FEC decoding of a word, corresponding to a bit sequence, received over a noisy channel, e.g. the channel 430, which word prior to transmission over the noisy channel was a codeword according to a LBC.

The apparatus(es) 600 may comprise processing module(s) 601, such as a means, one or more hardware modules, including e.g. one or more processors, and/or one or more software modules, e.g. corresponding to or being based on the functional blocks of FIG. 4, for performing said method and/or actions.

The apparatus(es) 600 may further comprise memory 602 that may comprise, such as contain or store, computer program(s) 603. The computer program(s) 603 comprises ‘instructions’ or ‘code’ directly or indirectly executable by the apparatus(es) 600 to perform said method and/or actions. The memory 602 may comprise one or more memory units and may further be arranged to store data, such as configurations and/or applications involved in or for performing functions and actions of embodiments herein.

Moreover, the apparatus(es) 600 may comprise processor(s) 604, i.e. one or more processors, as exemplifying hardware module(s) and may comprise or correspond to one or more processing circuits. In some embodiments, the processing module(s) 601 may comprise, e.g. ‘be embodied in the form of’ or ‘realized by’ processor(s) 604. In these embodiments, the memory 602 may comprise the computer program 603 executable by the processor(s) 604, whereby the apparatus(es) 600 is operative, or configured, to perform said method and/or actions thereof.

Typically the apparatus(es) 600, e.g. the processing module(s) 601, comprises Input/Output (I/O) module(s) 1005, configured to be involved in, e.g. by performing, any communication to and/or from other units and/or devices, such as sending and/or receiving information to and/or from other devices. The I/O module(s) 605 may be exemplified by obtaining, e.g. receiving, module(s) and/or providing, e.g. sending, module(s), when applicable.

Further, in some embodiments, the apparatus(es) 600, e.g. the processing module(s) 601, comprises one or more of an obtaining module(s), receiving module(s), computing module(s), generating module(s), forming module(s), determining module(s), as exemplifying hardware and/or software module(s) for carrying out actions of embodiments herein. These modules may be fully or partly implemented by the processor(s) 604.

### Hence:

The apparatus(es) 600, and/or the processing module(s) 601, and/or the processor(s) 604, and/or the I/O module(s) 605, and/or the obtaining module(s) are operative, or configured, to obtain said parity check matrix associated with the LBC.

The apparatus(es) 600, and/or the processing module(s) 601, and/or the processor(s) 604, and/or the I/O module(s) 605, and/or the receiving module(s) are operative, or configured, to receive said word.

The apparatus(es) 600, and/or the processing module(s) 601, and/or the processor(s) 604, and/or the I/O module(s) 605, and/or the computing module(s) are operative, or configured, to compute the syndrome for the received word using the obtained parity check matrix.

The apparatus(es) 600, and/or the processing module(s) 601, and/or the processor(s) 604, and/or the I/O module(s) 605, and/or the generating module(s) are operative, or configured, to generate said one or more noise sequences.

The apparatus(es) 600, and/or the processing module(s) 601, and/or the processor(s) 604, and/or the I/O module(s) 605, and/or the forming module(s) are operative, or configured, to form said candidate codewords for said noise sequences, respectively.

The apparatus(es) 600, and/or the processing module(s) 601, and/or the processor(s) 604, and/or the I/O module(s) 605, and/or the determining module(s) are operative, or configured, to determine if any one of said formed candidate codewords is said actual codeword according to said LBC.

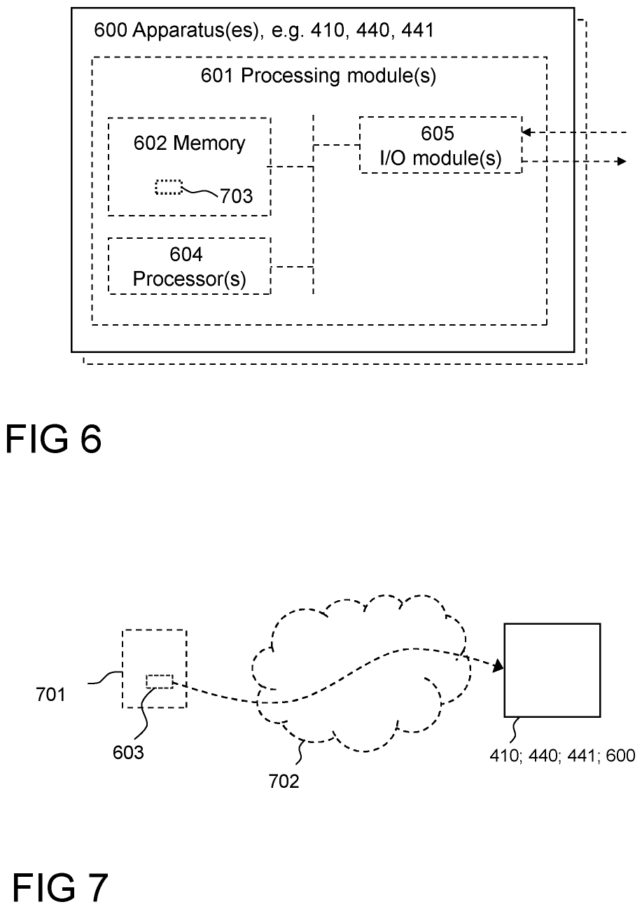

FIG. 7 is a schematic drawing illustrating some embodiments relating to computer program(s) and carriers thereof to cause said apparatus(es) 600 discussed above to perform said method and related actions. The computer program(s) may be the computer program(s) 603 and comprises instructions that when executed by the processor(s) 604 and/or the processing module(s) 601, cause the apparatus(es) 600 to perform as described above. In some embodiments there is provided carrier(s), or more specifically data carrier(s), e.g. computer program product(s), comprising the computer program(s). Each carrier may be one of an electronic signal, an optical signal, a radio signal, and a computer readable storage medium, e.g. a computer readable storage medium or media 701 as schematically illustrated in the figure. The computer program(s) 603 may thus be stored on such computer readable storage medium 701. By carrier may be excluded a transitory, propagating signal and the data carrier may correspondingly be named non-transitory data carrier. Non-limiting examples of the data carrier(s) being computer readable storage medium or media is a memory card or a memory stick, a disc storage medium, or a mass storage device that typically is based on hard drive(s) or Solid State Drive(s) (SSD). The computer readable storage medium or media 701 may be used for storing data accessible over a computer network 702, e.g. the Internet or a Local Area Network (LAN). The computer program(s) 603 may furthermore be provided as pure computer program(s) or comprised in a file or files. The file or files may be stored on the computer readable storage medium or media 701 and e.g. available through download e.g. over the computer network 702 as indicated in the figure, e.g. via a server. The file or files may e.g. be executable files for direct or indirect download to and execution on said apparatus(es) 600 to make it or them perform as described above, e.g. by execution by the processor(s) 604. The file or files may also or alternatively be for intermediate download and compilation involving the same or another processor(s) to make them executable before further download and execution causing said apparatus(es) 600 to perform as described above.

Note that any processing module(s) and circuit(s) mentioned in the foregoing may be implemented as a software and/or hardware module, e.g. in existing hardware and/or as an Application Specific Integrated Circuit (ASIC), a field-programmable gate array (FPGA) or the like. Also note that any hardware module(s) and/or circuit(s) mentioned in the foregoing may e.g. be included in a single ASIC or FPGA, or be distributed among several separate hardware components, whether individually packaged or assembled into a System-on-a-Chip (SoC).

Those skilled in the art will also appreciate that the modules and circuitry discussed herein may refer to a combination of hardware modules, software modules, analogue and digital circuits, and/or one or more processors configured with software and/or firmware, e.g. stored in memory, that, when executed by the one or more processors may make any node(s), device(s), apparatus(es), network(s), system(s), etc. to be configured to and/or to perform the above-described methods and actions.

Identification by any identifier herein may be implicit or explicit. The identification may be unique in a certain context, e.g. in the wireless communication network or at least in a relevant part or area thereof.

The term “network node” or simply “node” as used herein may as such refer to any type of node that may communicate with another node in and be comprised in a communication network, e.g. Internet Protocol (IP) network or wireless communication network. Further, such node may be or be comprised in a radio network node (described below) or any network node, which e.g. may communicate with a radio network node. Examples of such network nodes include any radio network node, a core network node, Operations & Maintenance (O&M), Operations Support Systems (OSS), Self Organizing Network (SON) node, etc.

Each of the terms “wireless communication device”, “wireless device”, “user equipment” and “UE”, as may be used herein, may as such refer to any type of wireless device arranged to communicate with a radio network node in a wireless, cellular and/or mobile communication system. Examples include: target devices, device to device UE, device for Machine Type of Communication (MTC), machine type UE or UE capable of machine to machine (M2M) communication, Personal Digital Assistant (PDA), tablet, mobile, terminals, smart phone, Laptop Embedded Equipment (LEE), Laptop Mounted Equipment (LME), Universal Serial Bus (USB) dongles etc.

Also note that although terminology used herein may be particularly associated with and/or exemplified by certain communication systems or networks, this should as such not be seen as limiting the scope of the embodiments herein to only such certain systems or networks etc.

As used herein, the term “memory” may refer to a data memory for storing digital information, typically a hard disk, a magnetic storage, medium, a portable computer diskette or disc, flash memory, random access memory (RAM) or the like. Furthermore, the memory may be an internal register memory of a processor.

Also note that any enumerating terminology such as first device or node, second device or node, first base station, second base station, etc., should as such be considered non-limiting and the terminology as such does not imply a certain hierarchical relation. Without any explicit information in the contrary, naming by enumeration should be considered merely a way of accomplishing different names.

As used herein, the expression “configured to” may e.g. mean that a processing circuit is configured to, or adapted to, by means of software or hardware configuration, perform one or more of the actions described herein.

As used herein, the terms “number” or “value” may refer to any kind of digit, such as binary, real, imaginary or rational number or the like. Moreover, “number” or “value” may be one or more characters, such as a letter or a string of letters. Also, “number” or “value” may be represented by a bit string.

As used herein, the expression “may” and “in some embodiments” has typically been used to indicate that the features described may be combined with any other embodiment disclosed herein.

In the drawings, features that may be present in only some embodiments are typically drawn using dotted or dashed lines.

As used herein, the expression “transmit” and “send” are typically interchangeable. These expressions may include transmission by broadcasting, uni-casting, group-casting and the like. In this context, a transmission by broadcasting may be received and decoded by any authorized device within range. In case of unicasting, one specifically addressed device may receive and encode the transmission. In case of group-casting, e.g. multicasting, a group of specifically addressed devices may receive and decode the transmission.

When using the word “comprise” or “comprising” it shall be interpreted as nonlimiting, i.e. meaning “consist at least of”.

The embodiments herein are not limited to the above described preferred embodiments. Various alternatives, modifications and equivalents may be used. Therefore, the above embodiments should not be taken as limiting the scope of the present disclosure, which is defined by the appending claims.

1. A method, performed by one or more apparatuses, for supporting forward error correction, FEC, decoding of a word, corresponding to a bit sequence, received over a noisy channel, which word prior to transmission over the noisy channel was a codeword according to a linear block code, LBC, the method comprising:
obtaining a parity check matrix associated with the LBC;
receiving the word;
computing the syndrome for the received word using the obtained parity check matrix;
generating one or more noise sequences to affect bits of the received word that are in one or more bit positions identified through parity check equations of the obtained parity check matrix that the computed syndrome for the received word identifies as erroneous parity check equations;
forming candidate codewords for the noise sequences, respectively, each candidate codeword corresponding to the received word with removal of noise according to a respective one of the noise sequences; and
determining if any one of the formed candidate codewords is an actual codeword according to the LBC by computing the syndrome for the candidate codeword using the obtained parity check matrix, the one or more noise sequences being generated to specifically affect bits in one or more first bit positions of the received word, which first bit positions are all bit positions, if any, checked by all of the erroneous parity check equations.

2. (canceled)

3. The method as claimed in claim 1, wherein one or more of the generating, forming and determining actions regarding the noise sequences to specifically affect bits in the one or more first bit positions are performed in response to that the number of first bit positions are below a certain first threshold number.

4. The method as claimed in claim 1, wherein the one or more noise sequences are generated to specifically affect bits in one or more second bit positions of the received word, which second bit positions are all bit positions checked by at least one of the erroneous parity check equations.

5. The method as claimed in claim 4, wherein one or more of the generating, forming and determining actions regarding the noise sequences to specifically affect bits in the second bit positions are performed in response to that the number of second bit positions are below a certain second threshold number.

6. The method as claimed in claim 3, wherein one or more of the generating, forming and determining actions regarding the noise sequences to specifically affect bits in the second bit positions are performed in response to that no candidate codeword was determined to be an actual codeword for said second bit positions of the received word are performed in response to that no candidate codeword was determined to be an actual codeword for the noise sequences generated to specifically affect bits of the received word in the one or more first bit positions, which second bit positions are all bit positions checked by at least one of the erroneous parity check equations.

7. The method as claimed in claim 1, wherein the generating, forming and determining actions are performed in response to that the computed syndrome for the received word identifies no more than a certain number of erroneous parity check equations.

8. (canceled)

9. (canceled)

10. One or more apparatuses for supporting forward error correction, FEC, decoding of a word, corresponding to a bit sequence, received over a noisy channel, which word prior to transmission over the noisy channel was a codeword according to a linear block code, LBC, the one or more apparatuses being configured to:
obtain a parity check matrix associated with the LBC;
receive the word;
compute the syndrome for the received word using the obtained parity check matrix;
generate one or more noise sequences to affect bits of the received word that are in one or more bit positions identified through parity check equations of the obtained parity check matrix that the computed syndrome for the received word identifies as erroneous parity check equations;
form candidate codewords for the noise sequences, respectively, each candidate codeword corresponding to the received word with removal of noise according to a respective one of the noise sequences; and
determine if any one of the formed candidate codewords is an actual codeword according to the LBC by computing the syndrome for the candidate codeword using the obtained parity check matrix, the one or more noise sequences being generated to specifically affect bits in one or more first bit positions of the received word, which first bit positions are all bit positions, if any, checked by all of the erroneous parity check equations.

11. (canceled)

12. The one or more apparatuses as claimed in claim 10, wherein one or more of the generating, forming and determining actions regarding the noise sequences to specifically affect bits in the one or more first bit positions are performed in response to that the number of first bit positions are below a certain first threshold number.

13. The one or more apparatuses as claimed in claim 10, wherein the one or more noise sequences are generated to specifically affect bits in one or more second bit positions of the received word, which second bit positions are all bit positions checked by at least one of the erroneous parity check equations.

14. The one or more apparatuses as claimed in claim 13, wherein one or more of the generating, forming and determining actions regarding the noise sequences to specifically affect bits in the second bit positions are performed in response to that the number of second bit positions are below a certain second threshold number.

15. The one or more apparatuses as claimed in claim 12, wherein one or more of the generating, forming and determining actions regarding the noise sequences to specifically affect bits in second bit positions of the received word are performed in response to that no candidate codeword was determined to be an actual codeword for the noise sequences generated to specifically affect bits of the received word in the one or more first bit positions, which second bit positions are all bit positions checked by at least one of the erroneous parity check equations.

16. The one or more apparatuses as claimed in claim 10, wherein the generating, forming and determining actions are performed in response to that the computed syndrome for the received word identifies no more than a certain number of erroneous parity check equations.

17. The method as claimed in claim 3, wherein the one or more noise sequences are generated to specifically affect bits in one or more second bit positions of the received word, which second bit positions are all bit positions checked by at least one of the erroneous parity check equations.

18. The method as claimed in claim 17, wherein one or more of the generating, forming and determining actions regarding the noise sequences to specifically affect bits in the second bit positions are performed in response to that the number of second bit positions are below a certain second threshold number.

19. The method as claimed in claim 3, wherein the generating, forming and determining actions are performed in response to that the computed syndrome for the received word identifies no more than a certain number of erroneous parity check equations.

20. The method as claimed in claim 4, wherein the generating, forming and determining actions are performed in response to that the computed syndrome for the received word identifies no more than a certain number of erroneous parity check equations.

21. The method as claimed in claim 5, wherein the generating, forming and determining actions are performed in response to that the computed syndrome for the received word identifies no more than a certain number of erroneous parity check equations.

22. The one or more apparatuses as claimed in claim 12, wherein the one or more noise sequences are generated to specifically affect bits in one or more second bit positions of the received word, which second bit positions are all bit positions checked by at least one of the erroneous parity check equations.

23. The one or more apparatuses as claimed in claim 22, wherein one or more of the generating, forming and determining actions regarding the noise sequences to specifically affect bits in the second bit positions are performed in response to that the number of second bit positions are below a certain second threshold number.

24. The one or more apparatuses as claimed in claim 12, wherein the generating, forming and determining actions are performed in response to that the computed syndrome for the received word identifies no more than a certain number of erroneous parity check equations.
